(19) United States
(12) Patent Application Publication
(10) Pub. No.: US 2012/0009347 A1
(43) Pub. Date: Jan. 12, 2012

(54) PRECISE TEMPERATURE CONTROL FOR TEOS APPLICATION BY HEAT TRANSFER FLUID

(75) Inventors: Dongsuh Lee, Santa Clara, CA (US); Weijie Wang, Cupertino, CA (US); William N. Sterling, Santa Clara, CA (US); Sam H. Kim, San Ramon, CA (US); Soo Young Choi, Fremont, CA (US); Beom Soo Park, San Jose, CA (US); Beom Soo Kim, Cupertino, CA (US); Qunhua Wang, San Jose, CA (US)

(73) Assignee: APPLIED MATERIALS, INC., Santa Clara, CA (US)

(21) Appl. No.: 12/831,731

(22) Filed: Jul. 7, 2010

(51) Int. Cl. C23C 16/52; B01F 15/06; C23C 16/00; B01F 15/02

(52) U.S. Cl. 427/248.1; 366/177.1; 366/144; 118/724

(57) ABSTRACT

Embodiments of the invention generally provide a mixing block for mixing precursors and/or cleaning agent which has the advantage of maintaining the temperature and improving the mixing effect of the precursors, cleaning agent or the mixture thereof to eliminate the substrate-to-substrate variation, thereby providing improved process uniformity.

### BACKGROUND OF THE INVENTION

1. Field of the Invention

The present invention relates to a mixing block for a CVD process.

2. Description of the Prior Art

In the manufacturing of integrated circuits, liquid crystal displays, flat panels and other electronic devices, multiple material layers are deposited onto and etched from substrates. The processing systems for manufacturing said devices typically include several vacuum processing chambers connected to a central transfer chamber to keep the substrate in a vacuum environment. Several sequential processing steps, such as physical vapor deposition (PVD), chemical vapor deposition (CVD), plasma enhanced CVD (PECVD), etching, and annealing, can be executed in said vacuum processing chambers respectively.

In some PECVD systems, TEOS (tetraethoxysilane) precursors are used to deposit silicon containing materials. In some systems, the TEOS precursors and cleaning agents travel through a common supply conduit. Temperatures rise within the conduit due to reactive activity by the cleaning gases may heat the conduit above the range desired for delivery of the TEOS precursor. Thus, process drift may occur after cleaning before the common conduit cools to a steady state temperature within the desired range. Moreover, static mixing elements disposed within the conduit cool slowly due to poor contact

Therefore, a need exists for an apparatus and method for maintaining the temperature of a mixing block.

### SUMMARY OF THE INVENTION

In one aspect of the invention, a mixing block for mixing precursors and/or cleaning agent is provided.

In one embodiment, a mixing block of the invention is formed from a single mass of material and comprises an integral mixing structure, two precursor delivery ports, a common outlet port and at least one passage. The integral mixing structure has a first chamber and a second chamber. The first chamber and the second chamber are separated by the mixing structure wherein the mixing structure is a unitary component of the mixing block. The two precursor delivery ports are coupled to the first chamber for respectively delivering at least one predetermined fluid. The common outlet port is coupled to the second chamber. Furthermore, the passage is formed in the mixing block for allowing a cooling fluid to flow through the mixing block. In some embodiments, the first chamber and the second chamber may be concentric bores formed in the mixing block and separated by the mixing structure, wherein the mixing structure can be a web of material which has an offset opening which creates turbulent flow as fluids move from the first chamber to the second chamber. The two precursor delivery ports can be a TEOS delivery port for delivering TEOS and an oxygen delivery port for delivering oxygen and/or NF₃ (Nitrogen Trifluoride) or other cleaning agents, wherein the TEOS delivery port and the oxygen delivery port are offset to promote turbulent mixing within the first chamber.

Another embodiment of the invention generally provides a CVD system comprising a mixing block previously described, a fan, and a heater. The fan positioned to blow air on an exterior of the mixing block. The heater is wrapped around the mixing block for heating the mixing block.

In comparison with the prior art, the present invention provides a mixing block formed by a single mass of material. The mixing block comprises an integral mixing structure having a first chamber and a second chamber. The first chamber and the second chamber are separated by a mixing element wherein the mixing element is a unitary component of the mixing block. Furthermore, at least one passage is formed in the mixing block for allowing a cooling fluid to flow through the mixing block. Accordingly, the mixing block of the invention is suitable for maintaining the temperature of the mixing block during both precursor delivery and cleaning within a predetermined range by heating or cooling the mixing block as needed.

The objective of the present invention will no doubt become obvious to those of ordinary skill in the art after reading the following detailed description of the preferred embodiment, which is illustrated in the following figures and drawings.

### BRIEF DESCRIPTION OF THE APPENDED DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 is a schematic view of one embodiment of a mixing block described herein.

FIG. 2 is a cross sectional view along line A-A of FIG. 1.

FIG. 3 is a cross sectional view along line B-B of FIG. 1.

FIG. 4 is a function block diagram of one embodiment of a CVD system described thereon.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the invention generally provide a mixing block for mixing precursors and/or cleaning agent which has the advantage of maintaining the temperature and improving the mixing effect of the precursors, cleaning agent or the mixture thereof to eliminate the substrate-to-substrate variation, thereby providing improved process uniformity.

The invention is illustratively described below in reference to a CVD system, for example, a PECVD system, available from AKT, a division of Applied Materials, Inc., Santa Clara, Calif. However, it should be understood that the invention has utility in other system configurations such as physical vapor deposition systems, ion implant systems, etch systems, chemical vapor deposition systems and any other systems that require a mixing block capable of maintaining the temperature of precursors is beneficial.

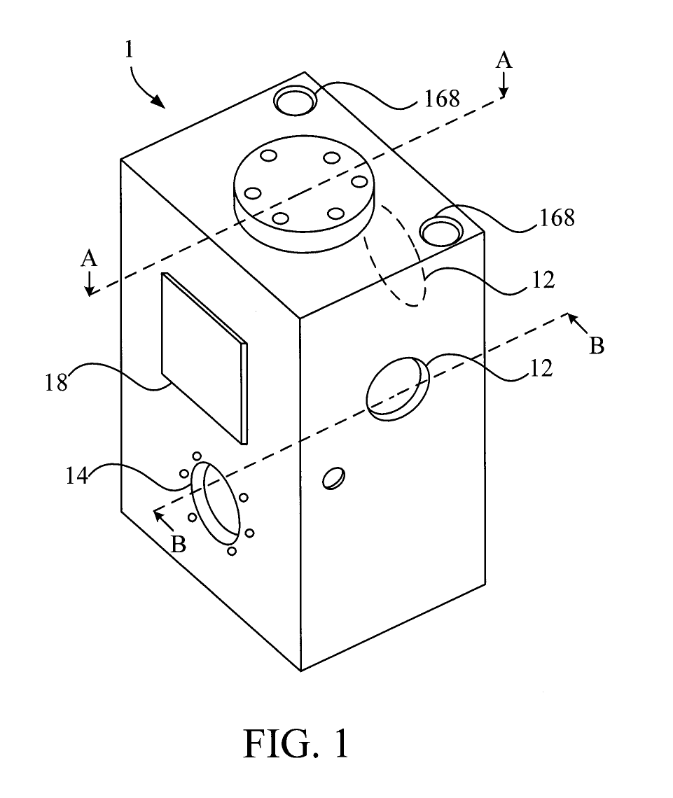

For clarity and ease of description, an actuation sequence of one embodiment of the invention is described below with reference with FIG. 1 to FIG. 4.

FIG. 1 is a schematic view of one embodiment of a mixing block described herein. The mixing block 1 of the invention comprises an integral mixing structure 16, two precursor delivery ports 12, a common outlet port 14 and at least one passage 168. The integral mixing structure 16 of the mixing block 1 is utilized for mixing the precursors and/or cleaning agents inputted from the precursor delivery ports 12 to form a mixture which exits the mixing block 1 at outlet port 14. Generally, the mixing block 1 has a body 10 that may be fabricated from a unitary block of material, for example, a metal such as aluminum or steel, due to the low manufacturing cost and high thermal conductivity. Other materials, such as polymers and ceramics, may alternately be utilized.

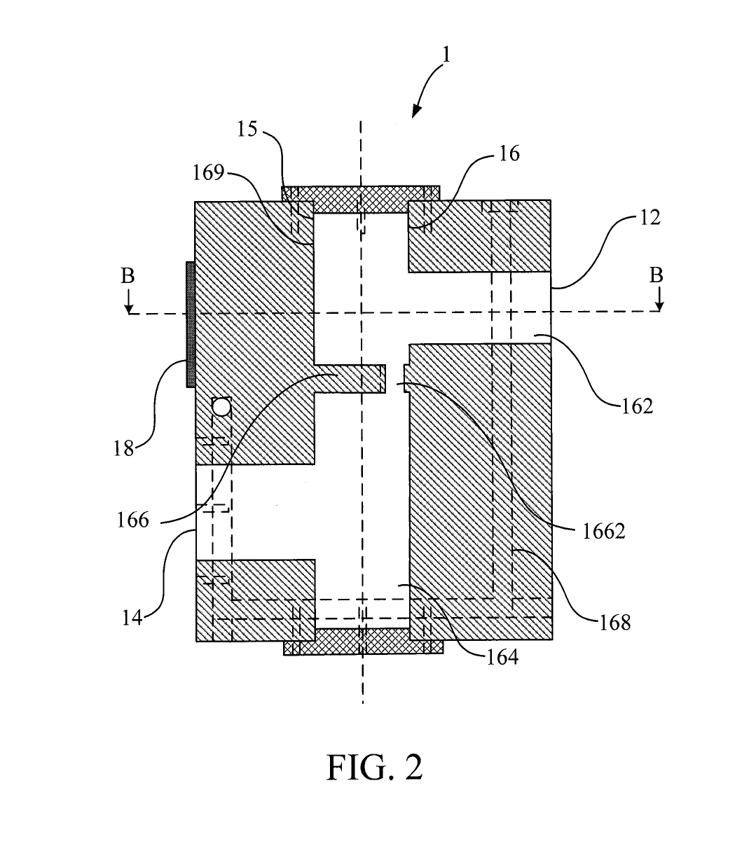

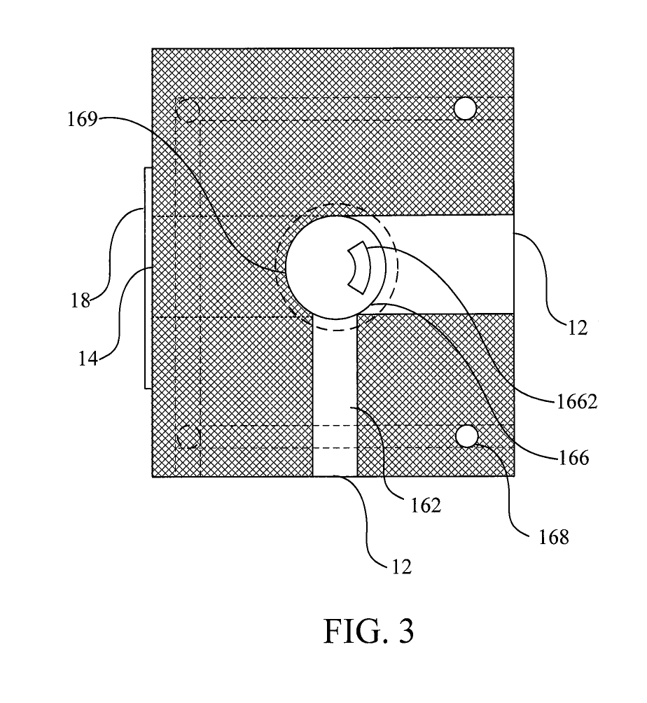

FIG. 2 is a cross sectional view along line A-A of FIG. 1. FIG. 3 is a cross sectional view along line B-B of FIG. 1. Referring to both FIG. 2 and FIG. 3, the integral mixing structure 16 is for mixing the precursors or cleaning agent inputted from the precursor delivery ports 12. The integral mixing structure 16 has a first chamber 162 and a second chamber 164. The first chamber 162 and the second chamber 164 are separated by a mixing element 166 which is integral to (e.g., part of) the body 10.

The first chamber 162 is defined as a volume spanning from the precursor delivery ports 12 to the mixing element 166. The second chamber 164 is defined as a volume spanning from the common outlet port 14 to the mixing element 166. The common outlet port 14 allows mixed precursors to exit the second chamber 164.

In the embodiment illustrated, the first chamber 162 and the second chamber 164 can be, but not limited to, formed by concentric bores 169 in the body 10 of the mixing block 1 and separated by the mixing element 166 of the mixing block 1. The mixing element 166 is a structure formed and extended from the periphery of the concentric bores 169, for example, a web of material. The mixing element 166 has an opening 1662 to create turbulent flow while the mixture of the precursors and/or the cleaning agent move from the first chamber 162 to the second chamber 164 for improving the mixing effect of the precursors and/or the cleaning agent.

The mixing element 166 is a unitary component of the body 10 of the mixing block 1, and thus is readily heated and cooled with the mixing block 1 to contribute good temperature control. In one embodiment, the opening 1662 of the mixing element 166 can be offset from the centerline of the first chamber 162 to promote turbulent flow. As the mixture of the precursors or the cleaning agent flow from the first chamber 162 to the second chamber 164, good mixingi of the precursors and/or the cleaning agent is realized.

The opening 1662 penetrates through the both surfaces of the mixing element 166 for allowing the precursors or cleaning agent, such as TEOS, oxygen, NF₃ or the mixture formed by the fluid thereof, to flow from the first chamber 162 to the second chamber 164.

The precursor delivery ports 12 are coupled to the first chamber 162 for respectively inputting at least one predetermined fluid into the first chamber 164. For example, two precursor delivery ports 12 can be a TEOS delivery port 12 for delivering TEOS and an oxygen delivery port 12 for delivering oxygen and/or NF₃ or other cleaning agents. The precursor delivery ports 12 may be offset to promote turbulent mixing within the first chamber 162. The term “offset” is used to describe that the orientation of the precursor delivery ports are arranged so that the fluid streams (i.e., the precursors or the cleaning agent) entering the first chamber 162 collide and promote mixing.

As shown in FIG. 2 and FIG. 3, the mixing block 1 comprises at least one passage 168 formed in the mixing block for allowing a cooling fluid to flow through the body 10 of the mixing block. The passage 168 has an inlet, disposed within the mixing block 1, for inputting a cooling fluid. The cooling fluid then flows along the passage 168 to absorb the heat from the body 10 of the mixing block 1. In the embodiment illustrated, the passage 168 is formed by perpendicularly interconnecting a plurality of plugged passage bores formed in the mixing block 1 for allowing the flow of the cooling fluid.

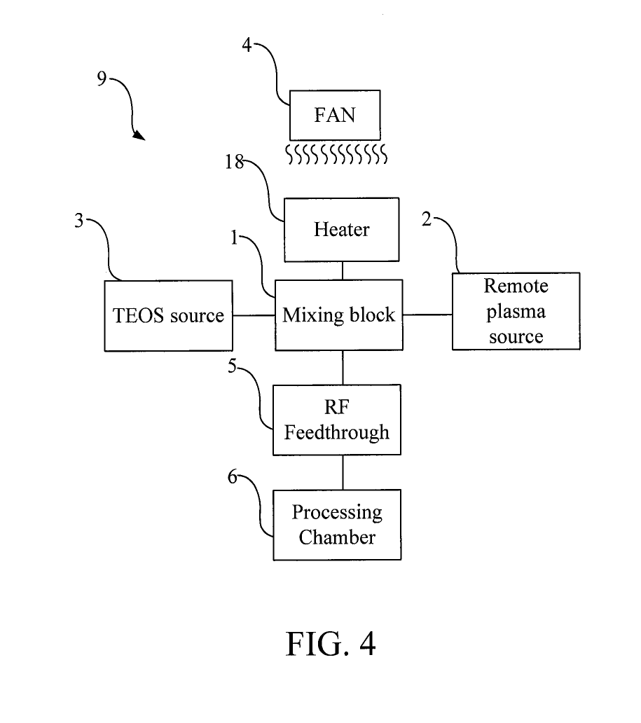

FIG. 4 is a functional block diagram of one embodiment of a CVD system described thereon. Referring to FIG. 4, embodiments of the present invention disclose a CVD system 9 comprising a mixing block 1, a fan 4 and one or more heaters 18. The heaters 18 may be band or cartridge heaters or other suitable heater.

The mixing block 1 comprises an integral mixing structure 16, two precursor delivery ports 12, a common outlet port 14 and at least one passage 168 previously described.

The precursor delivery ports 12 can be a TEOS delivery port 12 for delivering TEOS and an oxygen delivery port 12 for delivering oxygen and/or NF₃ or other cleaning agents into the mixing block 1. The oxygen delivery port 12 is coupled to a remote plasma source 2 and a gas panel that selectively provides either the cleaning agent or oxygen gas to the mixing block 1, through which oxygen or other process gases and/or NF₃ or other cleaning agents may be delivered. The remote plasma source 2 is energized to disassociate the NF₃ or other cleaning agents prior to enter the mixing block 1 during cleaning. The TEOS delivery port 12 is coupled to a TEOS source 3 for delivering TEOS to the mixing block 1.

The integral mixing structure 16 of the mixing block 1 is for mixing the precursors provided from the precursor delivery ports 12 to form a mixture. The mixture is then supplied to a processing chamber 6 via the common outlet port 14. Moreover, a RF feedthrough 5 couples the mixing block 1 to the processing chamber 6, where the mixture is delivered into the processing chamber 6 through an RF hot showerhead. The processing chamber 6 is a chamber for processing a substrate disposed therein using a CVD process, for example, depositing a layer of silicon.

Furthermore, while the precursors are mixed within the integral mixing structure 16 of the mixing block 1. The mixture of the precursors is generally kept between about 85-160° C., such as between about 100 to 130° C. This is achieved by heating the mixing block 1 using the heater 18 during the delivery of the precursor. Furthermore, by disposing the heaters 18 on the surface of the mixing block 1 or pipes connected with the precursor delivery ports or the common outlet port 14, the precursor can be heated before entering or after outputted from the mixing block 1. During delivery of precursors through the mixing block 1, the body 10 is not cooled (i.e., no coolant is provided through the passage 168). Alternatively, the body 10 may be heated by flowing hot fluid through the passage 168.

During cleaning, the heaters 18 are turned off, if needed, while the body 10 is cooled by flowing coolant through the passage 168 to remove heat generated by the cleaning agent. To further assist cooling the body 10, the fan 4 may be utilized to blow air on the exterior of the mixing block 1. the amount of cooling and/or heating during cleaning is selected to maintain the body 10 within the temperature range utilized during precursor delivery. Thus, when cleaning is complete, the temperature of precursor exiting the mixing block is substantially equal to the temperature of the precursor delivered just prior to cleaning, thereby minimizing substrate to substrate process deviations.

In comparison with the prior art, the present invention provides a mixing block 1 formed by a single mass of material. The mixing block 1 comprises an integral mixing structure 16 having a first chamber 162 and a second chamber 164. The first chamber 162 and the second chamber 164 are separated by a mixing element wherein the mixing element is a unitary component of the mixing block. Furthermore, at least one passage 168 is formed in the mixing block for allow a cooling fluid to flow through the mixing block 1. Accordingly, the mixing block 1 of the invention is capable of maintaining a constant temperature of the mixing block 1 during both precursor delivery and cleaning which needed to be heated and cooled respectively. In addition, the mixing block 1 of the invention is also capable of improving the mixing effect of the input precursors.

With the example and explanations above, the features and spirits of the embodiments of the invention are described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A mixing block comprising:
a body formed by a single mass of material;
an integral mixing structure having a first chamber and a second chamber, the first chamber and the second chamber being separated by a mixing element, wherein the mixing element is an unitary component of the body;
two precursor delivery ports formed in the body and coupled to the first chamber;
a common outlet port formed in the body and coupled to the second chamber; and
at least one passage formed in the body for allowing a temperature control fluid to flow through the body.

2. The mixing block of claim 1, wherein the first chamber and the second chamber are concentric bores separated by the mixing element.

3. The mixing block of claim 1, wherein the mixing element is a web of material.

4. The mixing block of claim 3, wherein the web of material has an offset opening.

5. The mixing block of claim 1 further comprising one or more heaters coupled to the body.

6. The mixing block of claim 1, wherein the delivery ports are offset to promote turbulent mixing within the first chamber.

7. A CVD system comprising:
a processing chamber;
a mixing block coupled to the processing chamber, the mixing block comprising:
a body;
a mixing structure integral to the body having a first chamber and a second chamber, the first chamber and the second chamber being separated by a mixing element wherein the mixing element is an unitary component of the body;
two precursor delivery ports formed through the body and coupled to the first chamber for respectively delivering at least one predetermined fluid;
a common outlet port formed through the body and coupled to the second chamber; and
at least one passage formed in the body for allowing a cooling fluid to flow through the mixing block; and
a fan positionable to cool the mixing block.

8. The CVD system of claim 7, wherein the first chamber and the second chamber are formed by concentric bores in the mixing block and separated by the mixing element.

9. The CVD system of claim 8, wherein the mixing element is a web of material.

10. The CVD system of claim 9, wherein the web of material has an offset opening.

11. The CVD system of claim 7, wherein two precursor delivery ports are coupled to a TEOS source and an oxygen source.

12. The CVD system of claim 7, wherein the delivery ports are offset to promote turbulent mixing within the first chamber.

13. The CVD system of claim 7, wherein the mixing block further comprises one or more heaters.

14. A method for processing a substrate comprising:
mixing precursors in a mixing block external to a processing chamber;
delivering the mixed precursors to the processing chamber;
processing a substrate in the presence of the mixed precursor in the processing chamber;
cleaning the mixing block; and
regulating a temperature of the mixing block during precursor mixing and cleaning to maintain the temperature within a predefined range.

15. The method of claim 14, wherein regulating further comprises:
heating the body during precursor delivery.

16. The method of claim 14, wherein regulating further comprises:
cooling the body during cleaning.
